(19) United States
(12) Patent Application Publication
(10) Pub. No.: US 2009/0183769 A1
(43) Pub. Date: Jul. 23, 2009

(54) Solar Cell Having Nanostructure and Method for Preparing the Same

(75) Inventors: LEEYIH WANG, Taipei (TW); YI-JUN LIN, Taipei (TW); WEN-YEN CHIU, Taipei (TW); WEI-FANG SU, Taipei (TW)

Correspondence Address: WPAT, PC, 7225 BEVERLY ST., ANNANDALE, VA, 22003, US

(73) Assignee: NATIONAL TAIWAN UNIVERSITY, Taipei (TW)

(21) Appl. No.: 12/015,690

(22) Filed: Jan. 17, 2008

(51) Int. Cl. H01L 31/0264; B05D 5/12; H01L 21/033

(52) U.S. Cl. 136/256; 427/74; 438/69; 257/E21.033

(57) ABSTRACT

The present invention discloses a solar cell having a multi-layered nanostructure that is used to generate, transport, and collect electric charges. The multi-layered nanostructure comprises a cathode, a hole-blocking layer, a photo-active layer, and an anode. The hole-blocking layer is made of the material selected from the group consisting of the following: inorganic semiconducting material, metal oxide material and mixture of inorganic and metal oxide materials. The photo-active layer comprises a porous body and a conjugated polymer filler. The porous body is used as an electron acceptor while the conjugate polymer filler is as an electron donor. The conjugated polymer filler is formed in the pores of the porous body by in-situ polymerization. In addition, the invention discloses a method for preparing the solar cell having a multi-layered nanostructure.

### BACKGROUND OF THE INVENTION

1. Field of the Invention

The present invention is generally related to a solar cell and a method for preparing the same, and more particularly to a solar cell having multi-layered nanostructure and a method for preparing the same.

2. Description of the Prior Art

At present, polymer solar cells attract great research interests because they have various advantages compared to the traditional silicon-based solar cells. For example, the low manufacturing energy and cost, light weight, flexibility and potential large-area fabrication, etc. However, the efficiency of polymer solar cell is still low. Thus, developing a high-efficiency polymer solar cell becomes an important research target.

The operating principle of polymer solar cells is as follows. When a polymer cell is irradiated by sun, the conjugated polymer in the polymer solar cell absorbs sunlight to have the electron in the highest occupied molecular orbital (HOMO) excited to the lowest unoccupied molecular orbital (LUMO) and then a hole is generated in HOMO to form an electron-hole pair, called exciton. The exciton can separate effectively at the interface between the electron acceptor and the electron donor, and then these free electrons and holes are transported to the external circuit to generate electric current. Thus, solar energy is transformed into electric energy. In the process of this energy conversion, solar cell efficiency is highly related to the mechanism of the separation of the electron-hole pair, the life time of the exciton, and the pathway of electric current transport.

Various bulk heterojunction photovoltaic devices have been developed using conjugated polymers as electron donor. Especially, polymers have been blended with inorganic nanoparticles to create donor/acceptor hybrids as photoactive materials for polymer solar cells. These hybrids polymer-inorganic solar cells utilize the high electron mobility of the inorganic phase to overcome charge-transport limitations associated with organic materials. It is very important to have the semiconductor nanoparticles randomly and homogeneously distributed in the conjugated polymers to increase the donor/acceptor interface. It also requires the formation of bi-continuous phases of nanoparticles and polymers to provide paths for the transport of hole and electron to anode and cathode, respectively. In such case, higher nanoparticle concentration is usually required to reach percolation threshold. However, when the nanoparticle concentration is high, coagulation of the nanoparticles may occur, leading to a decrease in both the donor/acceptor interfacial area and the photo-induced charge transfer efficiency.

At present, an important method to increase the interfacial area between the electron acceptor and the electron donor and to shorten the transport pathway of electrons or/and holes is firstly preparing a porous materials with nano-continuous structure, then coating conjugated polymers onto the surface of the substrate, and finally having conjugated polymers to penetrate into the pores by gravity, external forces, or heating to form an acceptor/donor mixture. However, polymers are long-chain molecules and thus they are not getting into the pores easily. It limits the ability to increase the area of the interface. Besides, in the method, polymers require good solubility in solvent but many conjugated polymer cannot dissolve in common organic solvents due to their rigid backbone. Therefore, the usable polymers are limited.

To solve the above-mentioned problems associated with the current method, the invention discloses a novel solar cell having multi-layered structure and a method for preparing the same.

### SUMMARY OF THE INVENTION

One main object of the present invention is to use in-situ polymerization technique to polymerize monomers and directly fill the pores of porous materials with thus-formed polymers. The conjugated polymer is an electron donor while the porous material is an electron acceptor. The conjugated polymer and the porous material act as a photo-active layer in a solar cell. Monomers are so small that they can easily penetrate the pores of the porous material. Then, the conjugated polymer material can be formed in the pores via the in-situ polymerization, thus to increase the interfacial area between the electron acceptor and the electron donor.

One object of the present invention is to have a wide choice of conjugate polymers. Since the conjugate polymers are prepared by the in-situ polymerization according to the invention, the solvent-dissolvable monomers are more than the solvent-dissolvable conjugate polymers. Thus, the invention provides convenient processing procedures, besides a wide variety of usable conjugate polymers can be used according to the invention. Therefore, this present invention does have the economic advantages for industrial applications.

Accordingly, the present invention discloses a solar cell having a multi-layered structure that is use to generate, transport, and collect electric charges. The multi-layered nanostructure comprises a cathode, a hole-blocking layer, a photo-active layer, and an anode. The hole-blocking layer is made of inorganic semiconducting material, metal oxide material, or mixture of inorganic and metal oxide materials. The photo-active layer comprises a porous body and a conjugated polymer filler. The porous body is used as an electron acceptor while the conjugate polymer filler is as an electron donor. The conjugated polymer filler is formed in the pores of the porous body by in-situ polymerization. In addition, the invention discloses a method for preparing a solar cell.

### BRIEF DESCRIPTION OF THE DRAWINGS

FIG. 1 shows a schematic diagram illustrating a solar cell having a multi-layered structure according to example 1 of the invention;

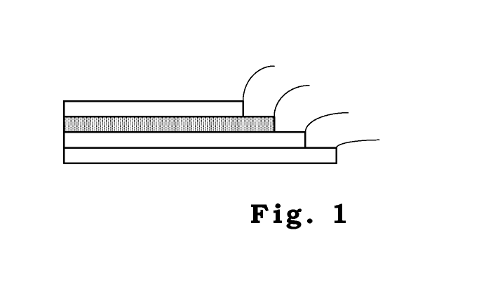

FIG. 2 shows scanning electron microscope (SEM) images of TiO₂ hole-blocking layers formed by spraying different number of layers according to example 5 of the present invention, where (a) FTO surface; (b) one layer; (c) three layers; (d) five layers; and (e) thirty layers; and

FIG. 3 shows the I-V characteristic curves of the solar cell comprised of the TiO₂ hole-blocking layers formed by spraying pyrolysis deposition method with different number of spraying cycles according to example 5 of the present invention.

### DESCRIPTION OF THE PREFERRED EMBODIMENTS

What is probed into the invention is a solar cell having a multi-layered nanostructure and a method for preparing the same. Detail descriptions of the structure and elements will be provided in the following in order to make the invention thoroughly understood. Obviously, the application of the invention is not confined to specific details familiar to those who are skilled in the art. On the other hand, the common structures and elements that are known to everyone are not described in details to avoid unnecessary limits of the invention.

The present invention discloses a solar cell having a multi-layered nanostructure that is use to generate, transport, and collect electric charges. The multi-layered nanostructures comprise a cathode, a hole-blocking layer, a photo-active layer, and an anode. The hole-blocking layer is made of inorganic semiconducting material, metal oxide material, or mixtures of inorganic and metal oxide materials. The photo-active layer comprises a porous body and conjugated polymer filler. The porous body is used as an electron acceptor while the conjugate polymer filler is as an electron donor. The conjugate polymer filler is formed in the pores of the porous body by in-situ polymerization. The in-situ polymerization is the polymerization reaction for forming conjugate polymers under the existence of the porous body.

The material of the above-mentioned hole-blocking layer is an inorganic semiconductor, metal oxide, or mixture of inorganic and metal oxide materials; preferably the material(s) selected from the group consisting of the following or any combination of the following: II/VI group, III/V group, and IV/IV group semiconductors; and more preferably the material(s) selected from the group consisting of the following or any combination of the following: TiO₂, CdS, CdSe, GaAs, GaP, ZnO, Fe₂O₃, SnO₂, SiC, InN, InGaN, GaN, PbS, Bi₂S₃, Cu—In—Ga—Se, and Cu—In—Ga—S.

The material of the porous body is an inorganic semiconductor, metal oxide, or mixture of inorganic and metal oxide materials; preferably the material(s) selected from the group consisting of the following or any combination of the following: II/VI group, III/V group, and IV/IV group semiconductors; and more preferably the material(s) selected from the group consisting of the following or any combination of the following: TiO₂, CdS, CdSe, GaAs, GaP, ZnO, Fe₂O₃, SnO₂, SiC, InN, InGaN, GaN, PbS, Bi₂S₃, Cu—In—Ga—Se, and Cu—In—Ga—S. The hole-blocking layer and the porous body in the solar cell according to the invention can be made of the same material or different materials.

In addition, the material of the cathode in the solar cell is selected from the group consisting of the following or any combination of the following: polymer, oligomer, organic small molecule, metal, or metal oxide. Preferably, it is selected from the group consisting of the following or any combination of the following: PEDOT:PSS, PEDOT, Al, Au, Pt, Ca, Mg, Ag, LiF, AZO (aluminum doped zinc oxide), ZnO, ITO (indium tin oxide), FTO (fluorine-doped tin oxide), and so forth. The material of the anode in the solar cell is selected from the group consisting of the following or any combination of the following: polymer, oligomer, organic small molecule, metal, or metal oxide. Preferably, it is selected from the group consisting of the following or any combination of the following: PEDOT:PSS, PEDOT, Al, Au, Pt, Ca, Mg, Ag, LiF, AZO (aluminum doped zinc oxide), ZnO, ITO (indium tin oxide), FTO (fluorine-doped tin oxide), and so forth. The cathode and the anode can be made of the same material or different materials.

The conjugated polymer filler is a polymer, oligomer, macromolecule, or copolymer comprising a conjugated structure, preferably comprising the substance(s) selected from the group consisting of the following or any combination of the following: polyanilines and derivatives thereof; polypyrroles and derivatives thereof; polythiophenes and derivatives thereof; poly(p-phenylene vinylene) and derivatives thereof; and polymer, oligomer or copolymer containing the structure of aniline, pyrrole, thiophene, p-phenylene vinylene or derivatives thereof. More preferably, it comprises the substance(s) selected from the group consisting of the following or any combination of the following: poly(3-akylthiophene), poly[2-methoxy, 5-(2-ethylhexoxy)-1, 4-phylene vinylene] (MEH-PPV), polybithiophene, polyaniline, polythiophene, MDMO-PPV, poly(3,4-ethylenedioxythiophene) (PEDOT), and polypyrrole.

The invention also provides a method for preparing a solar cell. At first, a cathode is provided. Then, a hole-blocking layer is formed on the cathode wherein the hole-blocking layer is made of the material(s) selected from the group consisting of the following or any combination of the following: inorganic material, metal oxide material and mixture of inorganic and metal oxide materials. Next, a porous body is formed on the hole-blocking layer as an electron acceptor. A solution comprising at least one organic molecule is provided and then contacts with the porous body to carry out in-situ polymerization reaction to form a conjugate polymer filler as an electron donor in the pores of the porous body wherein the porous body and the conjugate polymer filler function together as a photo-active layer in the solar cell. Finally, an anode is formed on the photo-active layer.

The material of the above-mentioned cathode is selected from the group consisting of the following or any combination of the following: polymer, oligomer, organic small molecule, metal, or metal oxide. Preferably, it is selected from the group consisting of the following or any combination of the following: PEDOT:PSS, PEDOT, Al, Au, Pt, Ca, Mg, Ag, LiF, AZO (aluminum doped zinc oxide), ZnO, ITO (indium tin oxide), FTO (fluorine-doped tin oxide), and so forth. The cathode is formed on the transparent substrate by evaporating, sputtering, or coating.

The material of the hole-blocking layer is an inorganic semiconductor, metal oxide, or mixture of inorganic and metal oxide materials; preferably the material(s) selected from the group consisting of the following or any combination of the following: II/VI group, III/V group, and IV/IV group semiconductors; and more preferably the material(s) selected from the group consisting of the following or any combination of the following: TiO₂, CdS, CdSe, GaAs, GaP, ZnO, Fe₂O₃, SnO₂, SiC, InN, InGaN, GaN, PbS, Bi₂S₃, Cu—In—Ga—Se, and Cu—In—Ga—S. The hole-blocking layer is formed by the method(s) selected from the group consisting of the following or any combination of the following: sol-gel method, electroplating method, chemical vapor deposition method, physical vapor deposition method, self-assembly method, spraying pyrolysis method, coating method, evaporation method, or sputtering method.

The material of the porous body is an inorganic semiconductor, metal oxide, or mixture of inorganic and metal oxide materials; preferably the material(s) selected from the group consisting of the following or any combination of the following: II/VI group, III/V group, and IV/IV group semiconductors; and more preferably the material(s) selected from the group consisting of the following or any combination of the following: TiO₂, CdS, CdSe, GaAs, GaP, ZnO, Fe₂O₃, SnO₂, SiC, InN, InGaN, GaN, PbS, Bi₂S₃, Cu—In—Ga—Se, and Cu—In—Ga—S. The porous body is formed by the method(s) selected from the group consisting of the following or any combination of the following: sol-gel method, electroplating method, chemical vapor deposition method, physical vapor deposition method, self-assembly film forming method, spraying pyrolysis method, coating method, evaporation method, or sputtering method. The hole-blocking layer and the porous body in the solar cell according to the invention can be made of the same material or different materials.

The conjugated polymer filler is a polymer, oligomer, macromolecule, or copolymer comprising a conjugated structure; preferably comprising the substance(s) selected from the group consisting of the following or any combination of the following: polyanilines and derivatives thereof; polypyrroles and derivatives thereof; polythiophenes and derivatives thereof; poly(p-phenylene vinylene) and derivatives thereof; and polymer, oligomer or copolymer containing the structure of aniline, pyrrole, thiophene, p-phenylene vinylene or derivatives thereof. More preferably, it comprises the substance(s) selected from the group consisting of the following or any combination of the following: poly(3-akylthiophene), poly[2-methoxy, 5-(2-ethylhexoxy)-1, 4-phylene vinylene] (MEH-PPV), polybithiophene, polyaniline, polythiophene, MDMO-PPV, poly(3,4-ethylenedioxythiophene) (PEDOT), and polypyrrole.

The in-situ polymerization reaction is the electropolymerization reaction, oxidative polymerization reaction, coupling polymerization reaction, radical polymerization reaction, ionic polymerization reaction, ring-opening polymerization reaction, and condensation polymerization reaction carried out under the existence of the porous body. Preferably, it is the electropolymerization reaction, oxidative polymerization reaction, or coupling polymerization reaction.

The material of the anode is selected from the group consisting of the following or any combination of the following: polymer, oligomer, organic small molecule, metal, or metal oxide. Preferably, it is selected from the group consisting of the following or any combination of the following: PEDOT:PSS, PEDOT, Al, Au, Pt, Ca, Mg, Ag, LiF, AZO (aluminum doped zinc oxide), ZnO, ITO (indium tin oxide), FTO (fluorine-doped tin oxide), and so forth. The anode is formed on the transparent substrate by evaporating, sputtering, or coating.

The details and implementing method of the invention are further illustrated by way of the following examples. However, these examples are only for illustration but not to confine the scope of the invention.

### Example 1

### Spray Pyrolysis Deposition of TiO₂ Hole-Blocking Layer

The TiO₂ compact layer was prepared by spray pyrolysis deposition. Precursor di-isopropoxy titanium bis(acetylacetonate) [Ti(acac)₂(i-C₃H₇O)₂] was synthesized in an inert gas atmosphere by the dropwise addition of acetylacetone to a stirred solution of [Ti(i-C₃H₇O)₄] (molar ratio 2:1). A solution of [Ti(acac)₂(i-C₃H₇O)₂+2 i-C₃H₇OH] (TAA) was thus formed and stored in an atmosphere of nitrogen prior to use. 2 M of TAA solution was diluted with ethanol to 0.2 M immediately before each coating process. The aerosol was prepared using a chromatographic atomizer. Before spraying, the handheld device was directed onto the sample, and the distance between the sample and the atomizer was maintained at 19-20 cm. Thin films of TiO₂ were prepared using a particular number of repetitions of single spraying steps. A surface of 25.0 mm×10.0 mm in most cases underwent one spraying step, followed by a 30s break before subsequent spraying. Three to 20 repetitions of this cycle finally yielded the TiO₂ layer. The device was thermally equilibrated on a hotplate maintained at 450° C. for at least 5 minutes before the spray-coating process and left for at least 10 minutes following each deposition cycle. After the required number of spraying cycles, the substrates were cleaned carefully by dried THF, and then annealed at 450° C. for another hour before being cooled to room temperature.

### Example 2

### Preparation and Sintering of Nanoporous TiO₂ Film

Titanium isopropoxide, 2-propanol and nitric acid were purchased from Acros and used without further purification. TiO₂ colloid dispersions were prepared by the sol-gel reaction of titanium isopropoxide, Ti(OCH(CH₃)₂)₄, as follows. Under a stream of dry nitrogen, 25 mL of Ti(OCH(CH₃)₂)₄ was added via a drooping funnel to 4 mL of 2-propanol. The mixture was added to 150 mL of deionized water over 10 min with vigorous stirring. Within 10 min of the addition of alkoxide, 1.14 mL of 65% nitric acid was further added to the system. The reaction was continued for 8 h at 80° C. The resulting sol was then concentrated in a vacuum at room temperature until the TiO₂ concentration was about 80 gL⁻¹. Finally, two drops of nonionic surfactant, Triton-X 100, were added to the solution and the solution was then stirred for several hours to enhance the colloidal stability and size uniformity of TiO₂.

Nanocrystalline TiO₂ was deposited on the compact TiO₂ layer by spin coating at a spin rate of 2500 rpm; heating to 450° C. at a heating rate of 4° C./min, and then being maintained at 450° C. for another 30 min before being cooled to temperature. The thickness of the nanocrystalline TiO₂ layer after sintering was around 80 nm.

### Example 3-1

### Electropolymerization of Bithiophene into Nanoporous Titania Films

Polybithiophene(PBiTh) was electrodeposited on the TiO₂ matrix using a three-electrode cell configuration. The working electrode was FTO glass coated with the compact and porous TiO₂ film, while Pt mesh and Ag/AgCl served as the counter electrode and reference electrode, respectively. PBiTh was electrodeposited in a mixed solution of 0.02 M 2,2′-bithiophene (Aldrich, 97%) and 0.01 M HClO₄ water/acetonitrile with a volume ratio of 1:1. The amount of polymer deposited on the working electrode was controlled by monitoring the total amount of charge consumed by the reaction, and the precipitated charge was maintained at 15 mC/cm². After the electrochemical preparation, the films were carefully rinsed with pure acetonitrile and washed by distilled water to remove any monomer residues. Then, the polymer film was cycled through a cathodic step of −0.4 V in monomer-free water/acetonitrile solution until the current was in the μA range, to yield PBiTh films in the neutral state. Finally, the polymer film was dried in vacuo for more than 2 h. Because PBiTh films were not dissolved in organic solvent, and could not washed off easily with solvent.

Finally, in the mixture solution of water and acetonitrile, the electrochemical property of the polybithiophene/TiO₂ composite film is characterized by cyclic voltammetry (CV).

### Example 3-2

### Electropolymerization of 3-Methylthiophene into Nanoporous Titania Films

Electropolymerization of 3-methylthiophene in nanoporous titania films was carried out in acetonitrile using Bu4 nNBF4 (Aldrich) as the electrolyte. Acetonitrile was distilled before use, while other chemicals were used as received. The monomer and electrolyte concentrations were 0.1 and 0.02 M, respectively. The electropolymerization was controlled by an Electrochemical Analyzer (CH Instrument, Model 614A) using platinum and Ag/AgCl as the counter electrode and reference electrode, respectively. During the electropolymerization, a constant potential of 2.0 V was applied for several minutes to establish a highly BF₄⁻ doped P3MeT layer on and inside the porous TiO₂ matrix. The samples were undoped at −0.8 V for 5 min then rinsed with fresh acetonitrile. The overgrown polymer layers were removed mechanically.

### Example 4

### Fabrication of Photovoltaic Cells

Photovoltaic cells were fabricated by electrochemical polymerization, followed by the evaporation deposition of an 80 nm-thick Au electrode in a vacuum. The effective cell area was adjusted to approximately 0.12 cm². I-V characteristics of the cell were measured with a Keithley SMU 2400 unit under AM 1.5G irradiation with an intensity of 100 mW/cm².

### Example 5

### Influence of TiO₂ Hole-Blocking Layer on the Performance of PBith/TiO₂ Solar Cells

At first, the precursor solution for spray pyrolysis deposition is synthesized. Precursor di-isopropoxy titanium bis(acetylacetonate) [Ti(acac)₂(i-C₃H₇O)₂] was synthesized in an inert gas atmosphere by the dropwise addition of acetylacetone to a stirred solution of [Ti(i-C₃H₇O)₄] (molar ratio 2:1). A solution of [Ti(acac)₂(i-C₃H₇O)₂+2 i-C₃H₇OH] (TAA) was thus formed and stored in an atmosphere of nitrogen prior to use. 2 M of TAA solution was diluted with ethanol to 0.2 M immediately before each coating process. The aerosol was prepared using a chromatographic atomizer. Before spraying, the handheld device was directed onto the sample, and the distance between the sample and the atomizer was maintained at 19-20 cm. Thin films of TiO₂ were prepared using a particular number of repetitions of single spraying steps. A surface of 25.0 mm×10.0 mm in most cases underwent one spraying step, followed by a 30s break before subsequent spraying. Three to 20 repetitions of this cycle finally yielded the TiO₂ layer. The device was thermally equilibrated on a hotplate maintained at 450° C. for at least 5 minutes before the spray-coating process and left for at least 10 minutes following each deposition cycle. After the required number of spraying cycles, the substrates were cleaned carefully by dried THF, and then annealed at 450° C. for another hour before being cooled to room temperature.

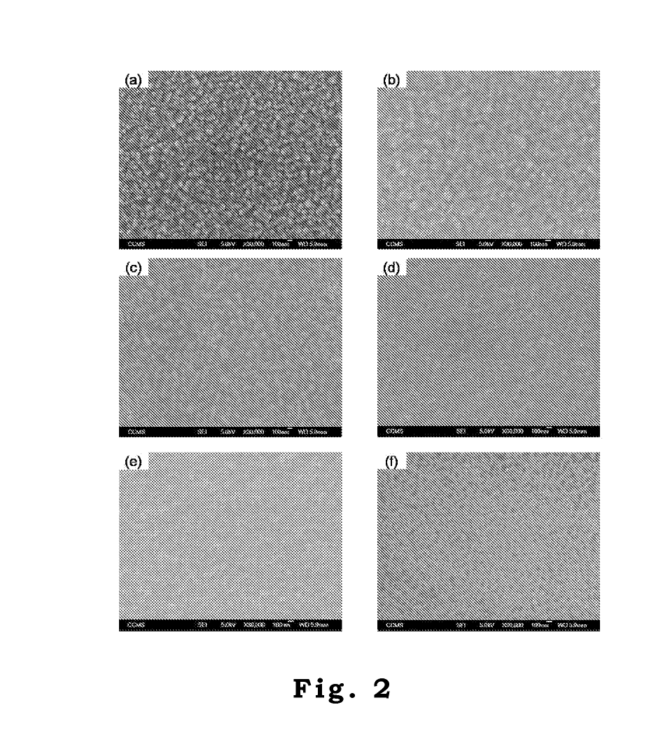

FIG. 2 show the SEM images of bare FTO glass and compact TiO₂ films on FTO glass. The bare FTO surface exhibits characteristic morphology of tin oxide crystals (FIG. 2a), and differs markedly from the smooth surface of ITO substrates (not shown). One spraying cycle of TiO₂ made the FTO surface smoother (FIG. 2b), but the edges of the FTO particles are still visible. TiO₂ was grown and sintered on top of the FTO particles, adopting the structure of the surface relief. FIG. 2c depicts the surface after three cycles of TiO₂ spray deposition. Most of the small FTO particles were covered by TiO₂, and the sharp edges of the larger FTO particles were rounded off by the deposition, such that the TiO₂ surface morphology is somewhat “smoothed”, but the shapes and contrast between the underneath FTO particles and the TiO₂ pattern on the surface can still just be recognized. As the spray deposition was increased to five or ten cycles (FIGS. 2d-2e), the sharp edges have almost completely disappeared because of the repeated efficient formation of compact layers. Only very small particles with gentle edge-curves are seen; the surface is smooth with very low roughness, and hardly any trace of the surface morphology of the starting FTO is preserved. However, the TiO₂ film became rough and cracked with an irregular and heterogeneous distribution of titania particles after 20 cycles of spray pyrolysis deposition, as shown in FIG. 2f. Obviously, the spraying deposition technique allows the thickness of the film to be easily controlled by varying the number of spraying cycles in the preparation of compact TiO₂ films, the film thickness of each layer was estimated to be around 2.5 nm. An uniform, strongly adhering and crack-free film can be produced in five to ten deposition cycles.

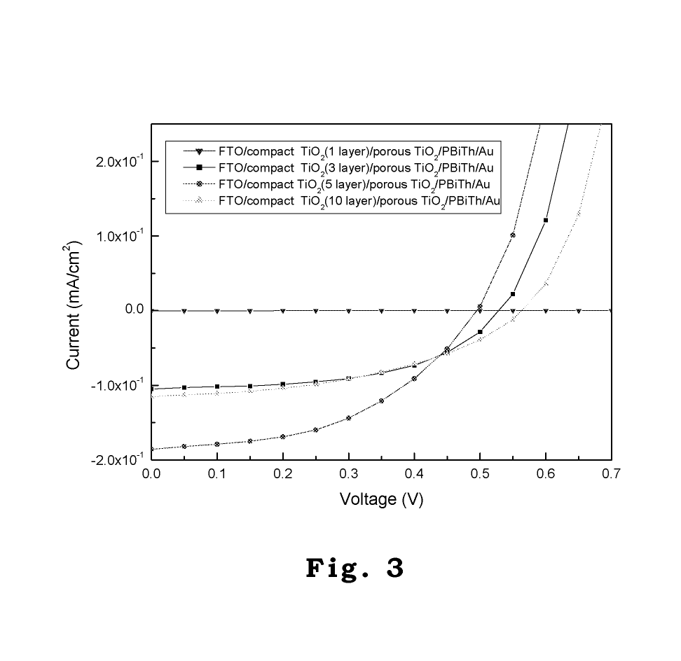

After metal electrode was evaporated, the device is assembled. FIG. 3 shows the I-V curves of selected solar cells with 1, 3, 5, 10 spraying cycles. The current-voltage characteristic values are shown in Table 1. From Table 1, the influence of the spraying number of TiO₂ hole-blocking deposited layers on the device efficiency can be seen. The existence of the TiO₂ hole-blocking layer obviously increases the open circuit voltage (V_{OC}), the short circuit current (I_{SC}), the fill factor (FF), and the device efficiency (η).

TABLE 1

| Device | V_{oc}(V) | I_{sc}(mA/cm²) | FF | η (%) |
|---|---|---|---|---|
| FTO/C—TiO₂ (1 | 0.44 | 3.18E−4 | 0.20 | 2.5E−5 |
| layer)/P—TiO₂—PBiTh/Au | | | | |
| FTO/C—TiO₂ (3 | 0.53 | 1.05E−1 | 0.51 | 0.0293 |
| layer)/P—TiO₂—PBiTh/Au | | | | |
| FTO/C—TiO₂ (5 | 0.50 | 1.86E−1 | 0.47 | 0.0432 |
| layer)/P—TiO₂—PBiTh/Au | | | | |
| FTO/C—TiO₂ (10 | 0.56 | 1.55E−1 | 0.46 | 0.0289 |
| layer)/P—TiO₂—PBiTh/Au | | | | |
| FTO/C—TiO₂ (10 | 0.32 | 2.51E−2 | 0.26 | 0.0020 |
| layer)/PBiTh—Au | | | | |

Obviously many modifications and variations are possible in apply of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A solar cell having multi-layered structure, the multi-layered structure comprising:
a cathode;
a hole-blocking layer wherein said hole-blocking layer is made of the material(s) selected from the group consisting of the following or any combination of the following: inorganic semiconductor material, metal oxide material, and mixture of inorganic and metal oxide materials;
a photo-active layer comprising a porous body and a conjugated polymer filler wherein said porous body is used as an electron acceptor and said the conjugated polymer filler is as an electron donor and is formed in the pores of the porous body by in-situ polymerization; and
an anode.

2. The solar cell according to claim 1, wherein the material of said cathode is the material(s) selected from the group consisting of the following or any combination of the following: polymer, oligomer, organic small molecule, metal, or metal oxide.

3. The solar cell according to claim 1, wherein material of said cathode is selected from the following group: PSS:PEDOT, PEDOT, ITO (indium tin oxide), or FTO (fluorine-doped tin oxide).

4. The solar cell according to claim 1, wherein the material of said hole-blocking layer is the material(s) selected from the group consisting of the following or any combination of the following: II/VI group, III/V group, and IV/IV group semiconductors.

5. The solar cell according to claim 1, wherein the material of said hole-blocking layer is the material(s) selected from the group consisting of the following or any combination of the following: TiO₂, CdS, CdSe, GaAs, GaP, ZnO, Fe₂O₃, SnO₂, SiC, InN, InGaN, GaN, PbS, Bi₂S₃, Cu—In—Ga—Se, and Cu—In—Ga—S.

6. The solar cell according to claim 1, wherein the material of said porous body is an inorganic semiconductor, metal oxide, or mixture of inorganic and metal oxide materials.

7. The solar cell according to claim 1, wherein the material of said porous body comprises the material(s) selected from the group consisting of the following or any combination of the following: TiO₂, CdS, CdSe, GaAs, GaP, ZnO, Fe₂O₃, SnO₂, SiC, InN, InGaN, GaN, PbS, Bi₂S₃, Cu—In—Ga—Se, and Cu—In—Ga—S.

8. The solar cell according to claim 1, wherein said porous body and said hole-blocking layer are made of the same material.

9. The solar cell according to claim 1, wherein said porous body and said hole-blocking layer are made of different materials.

10. The solar cell according to claim 1, wherein said conjugated polymer filler is a polymer, oligomer, macromolecule, or copolymer comprising a conjugated structure.

11. The solar cell according to claim 1, wherein the material of said conjugated polymer filler comprises the substance(s) selected from the group consisting of the following or any combination of the following: polyanilines and derivatives thereof; polypyrroles and derivatives thereof; polythiophenes and derivatives thereof; poly(p-phenylene vinylene) and derivatives thereof; and polymer, oligomer or copolymer containing the structure of aniline, pyrrole, thiophene, p-phenylene vinylene or derivatives thereof.

12. The solar cell according to claim 1, wherein the material of said conjugated polymer filler comprises the substance(s) selected from the group consisting of the following or any combination of the following: poly(3-akylthiophene), poly[2-methoxy, 5-(2-ethylhexoxy)-1, 4-phylene vinylene] (MEH-PPV), polybithiophene, polyaniline, polythiophene, MDMO-PPV, poly(3,4-ethylenedioxythiophene) (PEDOT), and polypyrrole.

13. A method for preparing a solar cell having multi-layered structure, the method comprising:
a cathode;
forming a hole-blocking layer on said cathode wherein said hole-blocking layer is made of the material(s) selected from the group consisting of the following or any combination of the following: inorganic semiconductor material, metal oxide material, and mixture of inorganic and metal oxide materials;
forming a porous body on said hole-blocking layer as an electron acceptor;
providing a solution comprising at least one organic molecule;
having said solution contacting with porous body to carry out in-situ polymerization reaction to form a conjugated polymer filler as an electron donor in the pores of said porous body wherein said porous body and said conjugated polymer filler function together as a photo-active layer in said solar cell; and
forming an anode on said photo-active layer.

14. The method according to claim 13, wherein the material of said cathode is the material(s) selected from the group consisting of the following or any combination of the following: polymer, oligomer, organic small molecule, metal, or metal oxide.

15. The method according to claim 13, wherein said cathode is formed by evaporating, sputtering, or coating.

16. The method according to claim 13, wherein the material of said hole-blocking layer is the material(s) selected from the group consisting of the following or any combination of the following: II/VI group, III/V group, and IV/IV group semiconductors.

17. The method according to claim 13, wherein the material of said hole-blocking layer is the material(s) selected from the group consisting of the following or any combination of the following: TiO₂, CdS, CdSe, GaAs, GaP, ZnO, Fe₂O₃, SnO₂, SiC, InN, InGaN, GaN, PbS, Bi₂S₃, Cu—In—Ga—Se, and Cu—In—Ga—S.

18. The method according to claim 13, wherein said hole-blocking layer is formed by the method(s) selected from the group consisting of the following or any combination of the following: sol-gel method, electroplating method, chemical vapor deposition method, physical vapor deposition method, self-assembly method, spray pyrolysis method, coating method, evaporation method, or sputtering method.

19. The method according to claim 13, wherein the material of said porous body is an inorganic semiconductor, metal oxide, or mixture of inorganic and metal oxide materials.

20. The method according to claim 13, wherein the material of said porous body comprises the material(s) selected from the group consisting of the following or any combination of the following: TiO₂, CdS, CdSe, GaAs, GaP, ZnO, Fe₂O₃, SnO₂, SiC, InN, InGaN, GaN, PbS, Bi₂S₃, Cu—In—Ga—Se, and Cu—In—Ga—S.

21. The method according to claim 13, wherein said porous body is formed by the method(s) selected from the group consisting of the following or any combination of the following: sol-gel method, electroplating method, chemical vapor deposition method, physical vapor deposition method, self-assembly film method, spray pyrolysis method, coating method, evaporation method, or sputtering method.

22. The method according to claim 13, wherein said in-situ polymerization reaction is electropolymerization reaction, oxidative polymerization reaction, coupling polymerization reaction, radical polymerization reaction, ionic polymerization reaction, ring-opening polymerization reaction, and condensation polymerization reaction, carried out under the existence of said porous body.

23. The method according to claim 13, wherein said in-situ polymerization reaction is electropolymerization reaction, oxidative polymerization reaction, or coupling polymerization reaction, carried out under the existence of said porous body.

24. The method according to claim 13, wherein said conjugate polymer filler is a polymer, oligomer, macromolecule, or copolymer comprising a conjugated structure.

25. The method according to claim 13, wherein the material of said conjugate polymer filler comprises the substance(s) selected from the group consisting of the following or any combination of the following: polyanilines and derivatives thereof; polypyrroles and derivatives thereof; polythiophenes and derivatives thereof; poly(p-phenylene vinylene) and derivatives thereof; and polymer, oligomer or copolymer containing the structure of aniline, pyrrole, thiophene, p-phenylene vinylene or derivatives thereof.
